(19) United States
(12) Patent Application Publication
(10) Pub. No.: US 2018/0100218 A1
(43) Pub. Date: Apr. 12, 2018

(54) Process for Forming a Cobalt-Iron Alloy Film on a Substrate

(71) Applicant: CHUNG YUAN CHRISTIAN UNIVERSITY, Tao-Yuan (TW)

(72) Inventors: Chih-Chi Chen, Tao-Yuan City (TW); Chang-Sheng Yeh, Tao-Yuan City (TW); Zong-Xun LI, Tao-Yuan City (TW)

(21) Appl. No.: 15/288,323

(22) Filed: Oct. 7, 2016

(51) Int. Cl. C22C 19/07; C09D 1/00; C09D 5/24; C23C 18/18; C23C 18/50; C23C 18/16; H05K 3/22; H05K 3/18; H05K 1/09; H01L 21/768; H01L 21/288; H01L 33/62; H01L 23/532

(52) U.S. Cl. CPC C22C 19/07; H01L 2933/0066; C09D 5/24; C23C 18/1806; C23C 18/1837; C23C 18/50; C23C 18/1637; C23C 18/1666; C23C 18/1676; H05K 3/22; H05K 3/181; H05K 1/09; H01L 21/76841; H01L 21/288; H01L 33/62; H01L 23/53238; H05K 2203/0307; C09D 1/00

(57) ABSTRACT

The invention relates to a process for forming a cobalt-iron alloy film. In particular, the process is performed under ultrasonic vibrations to form the cobalt-iron alloy film. The cobalt-iron alloy film consists of about 75-95 wt. % of cobalt, 4.5-20 wt. % of iron and 0.5-5 wt. % of phosphorus and also has peaks at about 43.2, 45.1, 50.4, 65.5, 74.1 and 83.2 2-theta degree (2θ) in the X-ray diffraction pattern.

### BACKGROUND OF THE INVENTION

### 1. Field of the Invention

This invention relates to a process for forming a cobalt-iron alloy film. In particular, the process is performed under ultrasonic vibrations to form the cobalt-iron alloy film with a special crystal form and low phosphorus content.

### 2. Description of the Prior Art

Traditionally, cobalt is effective in blocking copper diffusion and capable of being the potential diffusion barrier layer material in electronic packaging industry. However, a cobalt-iron alloy film with high phosphorus content ranges from 6 to 13wt. % was formed on a substrate, such as copper foil, in a conventional electroless plating process. The cobalt-iron alloy film with high phosphorus content ranges from 6 to 13 wt. % does not have an excellent diffusion barrier function.

The most difficult problem in conventional electroless plating process is the P-containing deposited thin films. In general, the crystallites of the deposited thin films are lower in the conventional electroless plating process, accordingly. Higher crystalline is required to develop to promotes the diffusion barrier function of the deposited thin films.

Based on the aforementioned, the important target of current industries is to develop a process which is able to form a cobalt-iron alloy film with low phosphorus content on varied substrates so as to promote the diffusion barrier function of the cobalt-iron alloy film.

### SUMMARY OF THE INVENTION

In accordance with the present invention, a process for forming a cobalt-iron alloy film on a substrate is disclosed. In particular, the process is performed under ultrasonic vibrations to form the cobalt-iron alloy film with a special crystal form and low phosphorus content. Therefore, the process substantially obviates one or more of the problems resulted from the limitations and disadvantages of the prior art mentioned in the background.

The first objective in the present invention is to disclose a process for forming a cobalt-iron alloy film on a substrate. The process comprises following steps: provide a substrate: apply a surface activation treatment to surfaces of the substrate to produce activated surfaces; provide a formulation which comprises a cobalt compound, a iron compound and a phosphorus compound and perform a coating process operated at 60-90° C. and under ultrasonic vibrations simultaneously to have the formulation form a cobalt-iron alloy film on the activated surfaces. The content of the cobalt-iron alloy film comprises about 75-95 wt. % of cobalt, 4.5-20 wt. % of iron and 0.5-5 wt. % of phosphorus.

In one embodiment, the substrate is made of one selected from the group consisting of Cu, Au, Al, Si, C and Al₂O₃.

In one embodiment, the surface activation treatment is performed in the presence of a palladium compound to produce the activated surfaces.

In one embodiment, the process further comprises surface roughening of the substrate and surface sensitizing of the substrate in the presence of a tin compound before applying the surface activation treatment.

In one embodiment, the formulation further comprises a buffering agent including boric acid (H₃BO₃), acetic acid and propionic acid, and a complexing agent including trisodium citrate (Na₃C₆H₅O₇), ammonium chloride (NH₄Cl), lactic acid, ethylenediamine (C₂H₄(NH₂)₂), and potassium sodium tartrate.

In one embodiment, pH value of the formulation is adjusted to a range of 10-13.

In another embodiment, the cobalt compound comprises CoCl₂ and CoSO₄.

In another embodiment, the iron compound comprises FeCl₂, FeCl₃, FeSO₄ and Fe₂(SO₄)₃.

In another embodiment, the phosphorus compound comprises NaH₂PO₂.

In a preferred embodiment, the formulation consists of 10-50 g/L of CoCl₂, 1-5 g/L of FeSO₄, 10-50 g/L of NaH₂PO₂, 10-50 g/L of H₃BO₃ and 100-200 g/L of Na₃C₆H₅O₇.

In a preferred embodiment, power of the ultrasonic vibrations is between 100 and 400 watts.

In a particular embodiment, the cobalt-iron alloy film has an X-ray powder diffraction pattern comprising peaks at about 43.2±0.2, 45.1±0.2, 50.4±0.2, 65.5±0.2, 74.1±0.2, and 83.2±0.2 2-theta degree.

In a particular embodiment, the aforementioned process is an electroless plating process.

According to the invention process, the cobalt-iron film with phosphorus content less than 6 wt. % is formed on the substrates. As a result, the cobalt-iron film has a higher degree of crystalline which is evidenced by X-ray diffraction analysis.

Another objective of the present invention is to provide a cobalt-iron alloy film which consists of about 75-95wt. % of cobalt, 4.5-20 wt. % of iron and 0.5-5wt. % of phosphorus. In addition, the cobalt-iron alloy film comprises peaks at about 43.2±0.2, 45.1±0.2, 50.4±0.2, 65.5±0.2, 74.1±0.2 and 83.2±0.2 2-theta degree in X-ray powder diffraction analysis.

In a certain embodiment, X-ray powder diffraction pattern of the cobalt-iron alloy film is shown in one selected from FIG. 2 and FIG. 3.

In another embodiment, the cobalt-iron alloy film has a thickness between 200 nm and 2000 nm.

In another embodiment, the cobalt-iron alloy film is part of a flip chip packaging, chip scale packaging or wafer level chip scale packaging.

In another embodiment, the cobalt-iron alloy film is part of a printed circuit board or a light-emitting diode device.

Accordingly, the present invention discloses the process for forming the cobalt-iron alloy film on the substrate. Particularly, the process is performed under ultrasonic vibrations to form the cobalt-iron alloy film on the substrate. Moreover, the cobalt-iron alloy film with low phosphorus content and a special X-ray diffraction pattern is provided in the invention.

### BRIEF DESCRIPTION OF THE DRAWINGS

The accompanying drawings incorporated in and forming a part of the specification illustrate several aspects of the present invention, and together with the description serve to explain the principles of the disclosure. In the drawings:

FIG. 1 shows the invention process flow diagram:

FIG. 2 shows the typical X-ray diffraction pattern of the claimed cobalt-iron alloy film:

FIG. 3 shows the X-ray diffraction pattern of the claimed cobalt-iron alloy film described in the second embodiment:

FIG. 4 shows the typical X-ray diffraction pattern of a cobalt-iron alloy film prepared without using ultrasonic vibrations: and

FIG. 5(a) shows the SEM image of the cobalt-iron alloy film formed at 65° C. without applying ultrasonic vibrations; FIG. 5(b) shows the SEM image of the cobalt-iron alloy film formed at 65° C. and under ultrasonic vibrations simultaneously at ultrasonic power 40 watts: FIG. 5(c) shows the SEM image of the cobalt-iron alloy film formed at 65° C. and under ultrasonic vibrations simultaneously at ultrasonic power 120 watts and FIG. 5(d) shows the SEM image of the cobalt-iron alloy film formed at 65° C.; and under ultrasonic vibrations simultaneously at ultrasonic power 200 watts.

### DETAILED DESCRIPTION OF THE PREFERRED EMBODIMENTS

What is probed into the invention is a process for forming a cobalt-iron alloy film. Detail descriptions of the structure and elements will be provided in the following in order to make the invention thoroughly understood. Obviously, the application of the invention is not confined to specific details familiar to those who are skilled in the art. On the other hand, the common structures and elements that are known to everyone are not described in details to avoid unnecessary limits of the invention. Some preferred embodiments of the present invention will now be described in greater detail in the following. However, it should be recognized that the present invention can be practiced in a wide range of other embodiments besides those explicitly described, that is, this invention can also be applied extensively to other embodiments, and the scope of the present invention is expressly not limited except as specified in the accompanying claims.

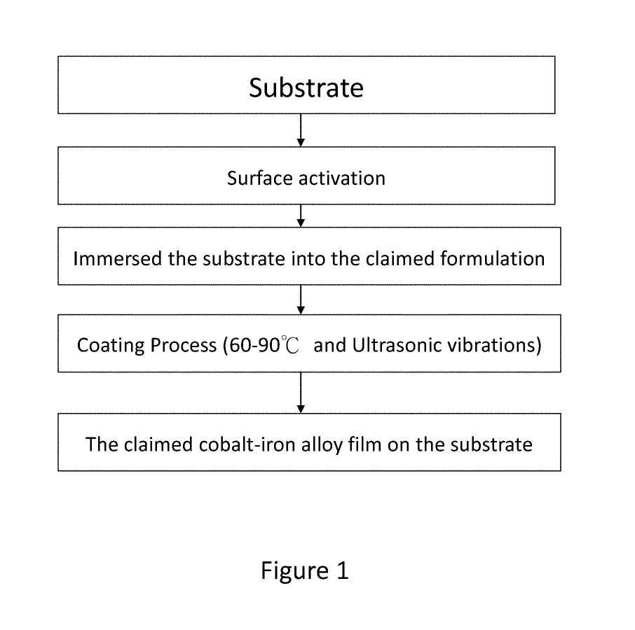

In a first embodiment of the present invention, a process for forming a cobalt-iron alloy film on a substrate is disclosed. The process as shown in FIG. 1 comprises the following steps provide a substrate; apply surface activation treatment to surfaces of the substrate to produce activated surfaces; provide a formulation which comprises a cobalt compound, a iron compound and a phosphorus compound and perform a coating process operated at 60-90° C. and under ultrasonic vibrations simultaneously to have the formulation form a cobalt-iron alloy film on the activated surfaces. The content of the cobalt-iron alloy film comprises about 75-95wt. % of cobalt, 4.5-20 wt. % of iron and 0.5-5 wt. % of phosphorus.

In one example of the first embodiment, the substrate is made of one selected from the group consisting of Cu, Au, Al, Si, C and Al₂O₃. Preferably, the substrate is Cu.

In one example of the first embodiment, the surface activation treatment is performed in the presence of a palladium compound to produce activated surfaces. Preferably, the palladium compound is palladium dichloride (PdCl₂).

In one example of the first embodiment, the process further comprises surface roughening of the substrate and surface sensitizing of the substrate in the presence of a tin compound before applying the surface activation treatment. Preferably, the tin compound is tin dichloride (SnCl₂).

In one example of the first embodiment, the formulation further comprises a buffering agent including boric acid (H₃BO₃), acetic acid and propionic acid, and a complexing agent including trisodium citrate (Na₃C₆H₅O₇), ammonium chloride (NH₄Cl), lactic acid, ethylenediamine (C₂H₄(NH₂)₂), and potassium sodium tartrate. Preferably, the buffering agent is boric acid, and the complexing agent is trisodium citrate (Na₃C₆H₅O₇).

In one example of the first embodiment, pH value of the formulation is adjusted to a range of 10-13. Preferably, the pH value of the formulation is adjusted to 11-12.

In another example of the first embodiment, the cobalt compound comprises CoCl₂ and CoSO₄.

In another example of the first embodiment, the iron compound comprises FeCl₂, FeCl₃, FeSO₄ and Fe₂(SO₄)₃.

In another example of the first embodiment, the phosphorus compound comprises NaH₂PO₂. Preferably, the phosphorus compound is NaH₂PO₂.

In a preferred example of the first embodiment, the formulation consists of 10-50 g/L of CoCl₂, 1-5 g/L of FeSO₄, 10-50 g/L of NaH₂PO₂, 10-50 g/L of H₃BO₃ and 100-200 g/L of Na₃C₆H₅O₇.

In a preferred example of the first embodiment, power of the ultrasonic vibrations is between 100 and 400 watts. More preferably, the power of the ultrasonic vibrations is between 120 and 200 watts.

In a particular example of the first embodiment, the cobalt-iron alloy film has an X-ray powder diffraction pattern comprising peaks at about 43.2±0.2, 45.1±0.2, 50.4±0.2, 65.5±0.2, 74.1±0.2, and 83.2±0.2 2-theta degree.

In a particular example of the first embodiment, the aforementioned process is an electroless plating process.

In a representative example of the first embodiment, copper (Cu) is used as the substrate. At first, surfaces of the copper is roughened by 20 wt. % of hydrochloride aqueous solution under ultrasonic vibrations and then washed with water. After the surface roughening, surface sensitizing is carried out in the presence of tin dichloride and then surface activation is performed in the presence of palladium dichloride. Therefore, the copper with activated surfaces is formed. A formulation which consists of 31.5 g/L of CoCl₂, 3.5 g/L of FeSO₄, 20 g/L of NaH₂PO₂, 30 g/L of H₃BO₃ and 140 g/L of Na₃C₆H₅O₇ is put into a beaker and then adjusted pH value of the formulation to 12 by adding sodium hydroxide. Finally, the copper with activated surfaces is immersed into the formulation and then perform a coating procedure at 65° C. and 200 watts ultrasonic vibrations simultaneously for 120 minutes to have the formulation form a cobalt-iron alloy film on the copper.

The aforementioned cobalt-iron alloy film on the copper is analyzed by SEM, X-ray diffraction analysis and element analysis. The element analysis shows that the cobalt-iron alloy film comprises about 90.8. wt of cobalt, 8.3 wt % of iron and 0.9 wt. % of phosphorus.

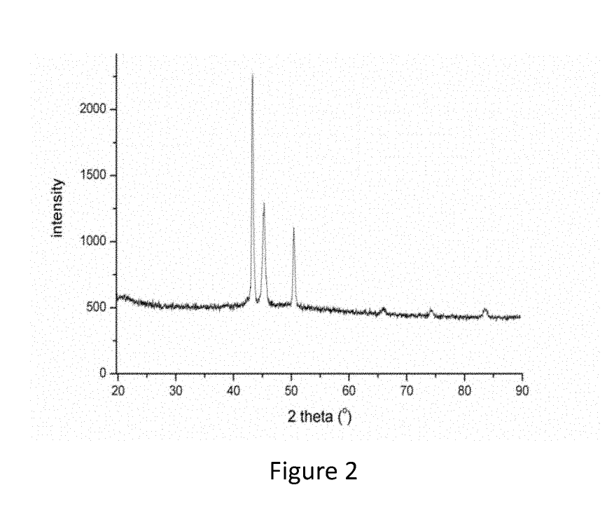

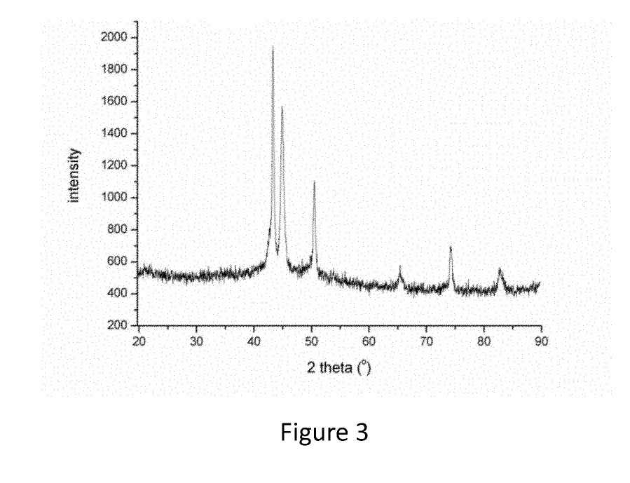

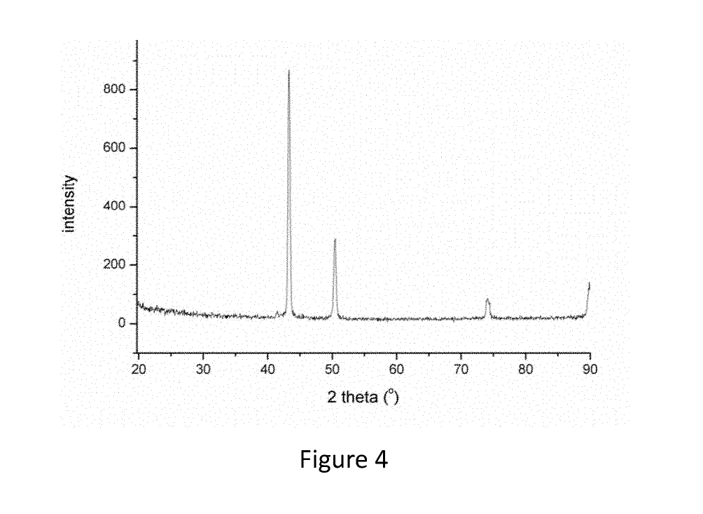

According to the invention process, the cobalt-iron film with phosphorus content less than 5 wt. % is formed on the substrate. In the meanwhile, crystalline degree of the cobalt-iron film with phosphorus content less than 5 wt. % increases and is evidenced by X-ray diffraction pattern as shown in both FIG. 2 and FIG. 3.

In a second embodiment, a cobalt-iron alloy film which consists of about 75-95wt. % of cobalt, 4.5-20 wt. % of iron and 0.5-5 wt. % of phosphorus is disclosed. In addition, the claimed cobalt-iron alloy film also comprises peaks at about 43.2±0.2, 45.1±0.2, 50.4±0.2, 65.5+0.2, 74.1±0.2 and 83.2±0.2 2-theta degree in X-ray powder diffraction pattern.

In a certain example of the second embodiment, the X-ray powder diffraction pattern of the cobalt-iron alloy film is shown in FIG. 3.

In another example of the second embodiment, the cobalt-iron alloy film has a thickness between 200 nm and 2000 nm.

In another example of the second embodiment, the cobalt-iron alloy film is part of a flip chip packaging, chip scale packaging or wafer level chip scale packaging.

In another example of the second embodiment, the cobalt-iron alloy film is part of a printed circuit board or a light-emitting diode device.

Accordingly, the present invention discloses a process for forming a cobalt--iron alloy film on a substrate. Particularly, the process is performed under ultrasonic vibrations to form the cobalt-iron alloy film on the substrate. In addition, the cobalt--iron alloy film with low phosphorus content and a special X-ray diffraction pattern is also provided in the invention.

Example: The preparation of the cobalt-iron alloy film on copper.

At first, surfaces of the copper was roughened by 20wt. % of hydrochloride aqueous solution under ultrasonic vibrations and then washed with water. After the surface roughening, surface sensitizing was carried out in the presence of tin dichloride (100 g/L). Removed the residual tin dichloride by washing with de-ionized water and then performed surface activation in the presence of palladium dichloride (1 g/L). After removing the residual palladium dichloride, the copper with activated surfaces was obtained. Prepared a formulation which consists of 31.5 g/L of CoCl₂, 3.5 g/L of FeSO₄, 20 g/L of NaH₂PO₂, 30 g/L of H₃BO₃ and 140 g/L of Na₃C₆H₅O₇ in a beaker. The formulation was then adjusted to pH value of 12 by adding 5M of sodium hydroxide. The copper with activated surfaces was immersed into the formulation and performed the coating procedure at 65° C. and under ultrasonic vibrations simultaneously for different times to have the formulation form the cobalt-iron alloy film on the copper. The cobalt-iron alloy film on the copper was analyzed by element analysis and the weight percentage of iron (Fe) in the cobalt-iron alloy film was shown in Table 1. The weight percentage of phosphorus (P) in the cobalt-iron alloy film was shown in Table 2.

TABLE 1
Fe wt. %

Watt

| | | | |
|---|---|---|---|
| time | 40 W | 120 W | 200 W |

| | | | | |
|---|---|---|---|---|
| 30 | min | 16.2 | 13 | 9 |
| 60 | min | 12.6 | 9 | 14 |
| 90 | min | 6.4 | 13 | 10.2 |
| 120 | min | 9.4 | 13 | 8.35 |

TABLE 2
P wt. %

Watt

| | | | |
|---|---|---|---|
| time | 40 W | 120 W | 200 W |

| | | | | |
|---|---|---|---|---|
| 30 | min | 4 | 2.4 | 1.9 |
| 60 | min | 2.9 | 1 | 2 |
| 90 | min | 2.8 | 2.4 | 0.9 |
| 120 | min | 2.9 | 1.5 | 0.9 |

The cobalt-iron alloy films were characterized by X-ray diffraction for checking their crystal forms and degree of crystalline.

The cobalt-iron alloy films formed according to the invention process have peaks at about 43.2, 45.1, 50.4, 65.5, 74.1 and 83.2 2-theta degree (2 0) and the peak intensity was shown in Table 3 and Table 4.

TABLE 3
pH = 11 T = 65° C. 200 W

| 2θ | intensity |
|---|---|
| 43.28 | 2272 |
| 45.3 | 1295 |
| 50.44 | 1107 |
| 65.95 | 506 |
| 74.07 | 503 |
| 83.44 | 499 |

TABLE 4
pH = 11 T = 85° C. 200 W

| 2θ | intensity |
|---|---|
| 43.28 | 1947 |
| 44.88 | 1573 |
| 50.48 | 1105 |
| 65.42 | 580 |
| 74.15 | 699 |
| 83.24 | 541 |

In contrast, cobalt-iron alloy films prepared without using ultrasonic vibration (0 watt) have different X-ray diffraction pattern. Moreover, the peak intensity as shown in Table 5 and Table 6 was obviously less than the peak intensity of the cobalt-iron films prepared by the present invention process. Accordingly, the invention process is able to produce the cobalt-iron alloy films with the unique crystals form and higher degree of crystalline.

TABLE 5
pH = 11 T = 65° C. 0 W

| 2θ | intensity |
|---|---|
| 43.3 | 868 |
| 50.45 | 290.667 |
| 74.1 | 86.6667 |

TABLE 6
pH = 11 T = 85° C. 0 W

| 2θ | intensity |
|---|---|
| 43.25 | 1066.67 |
| 50.4 | 558.667 |
| 74.15 | 395.333 |

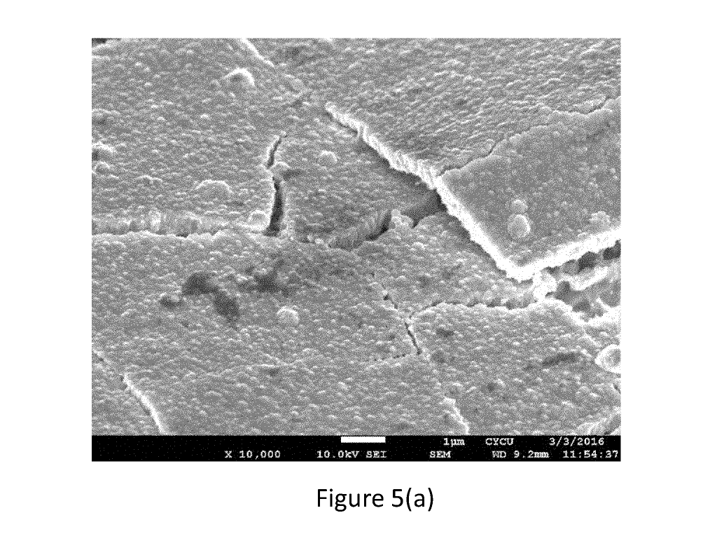

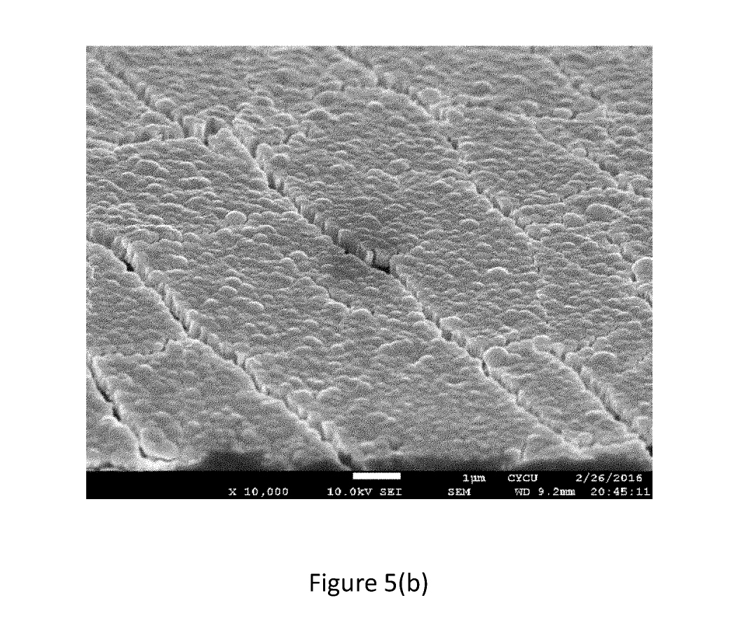

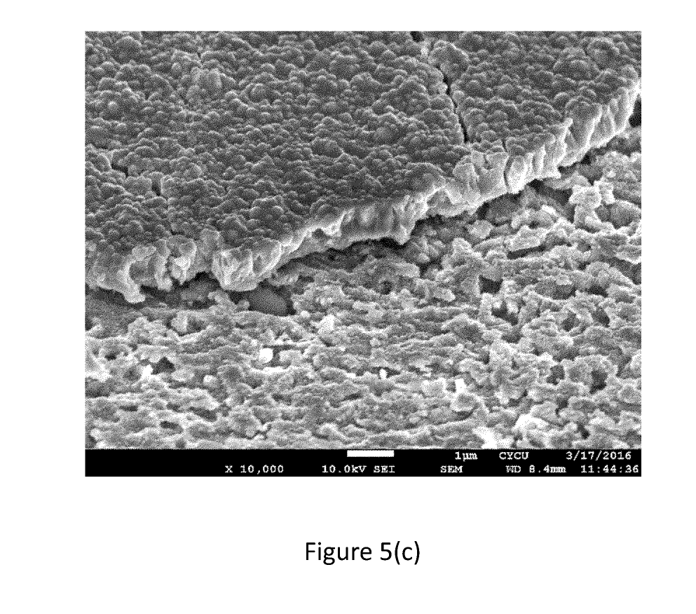

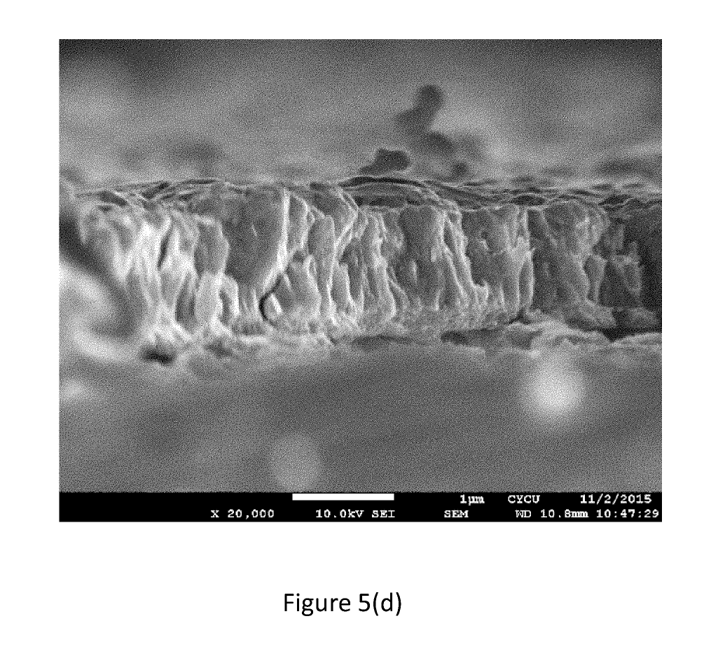

As shown in FIG. 5, SEM image analysis shows the effect of the power of the ultrasonic vibrations. When the power of the ultrasonic vibrations was 1.20 watts, the appearance of the film was obviously different from the one formed under lower power, such as 40 watts. Additionally, the thickness of the cobalt-iron alloy film formed under different conditions was listed in Table 7.

TABLE 7
thickness (nm)

Watt

| | | | | |
|---|---|---|---|---|
| time | 0 W | 40 W | 120 W | 200 W |

| | | | | | |
|---|---|---|---|---|---|
| 30 | min | 75 | 99 | 180 | 620 |
| 60 | min | 101.66 | 129 | 240 | 730 |
| 90 | min | 228.66 | 155 | 338 | 1500 |
| 120 | min | 232.66 | 219.6 | 610 | 1520 |

Although specific embodiments have been illustrated and described, it will be obvious to those skilled in the art that various modifications may be made without departing from what is intended to be limited solely by the appended claims.

What is claimed is:

1. A process for forming a cobalt-iron alloy film on a substrate, say process comprising:
providing a substrate;
applying a surface activation treatment to surfaces of the substrate to produce activated surfaces;
providing a formulation which comprises a cobalt compound, a iron compound and a phosphorus compound; and
performing a coating process operated at 60-90° C. and under ultrasonic vibrations simultaneously to have the formulation form a cobalt-iron alloy film on the activated surfaces, wherein the cobalt-iron alloy film comprises about 75-95 wt. % of cobalt, 4.5-20 wt. % of iron and 0.5-5 wt. % of phosphorus.

2. The process according to claim 1, wherein the substrate is made of one selected from the group consisting of Cu, Au, Al, Si, C and Al₂O₃.

3. The process according to claim 1, wherein the surface activation treatment is performed in the presence of a palladium compound.

4. The process according to claim 1, further comprising surface roughening of the substrate and surface sensitizing of the substrate in the presence of a tin compound before applying the surface activation treatment

5. The process according to claim 1, wherein the formulation further comprises a buffering agent including H₃BO₃, acetic acid and propionic acid, and a complexing agent including trisodium citrate (Na₃C₆H₅O₇), ammonium chloride (NH₄Cl), lactic acid, ethylenediamine (C₂H₄(NH₂)₂), and potassium sodium tartrate.

6. The process according to claim 1, wherein pH value of the formulation is adjusted to a range of 10-13.

7. The process according to claim 1, wherein the cobalt compound comprises CoCl₂ and CoSO₄.

8. The process according to claim 1, wherein the iron compound comprises FeCl₂, FeCl₃, FeSO₄ and Fe₂(SO₄)₃.

9. The process according to claim 1, wherein the phosphorus compound comprises NaH₂PO₂.

10. The process according to claim 1, wherein the formulation consists of 10-50 g/L of CoCl₂, 1-5 g/L of FeSO₄, 10-50 g/L of NaH₂PO₂, 10-50 g/L of H₃BO₃ and 100-200 g/L of Na₃C₆H₅O₇.

11. The process according to claim 1, wherein power of the ultrasonic vibrations is between 100 and 400 watts.

12. The process according to claim 1, wherein the cobalt-iron alloy film has an X-ray powder diffraction pattern comprising peaks at about 43.2±0.2, 45.1±0.2, and 50.4±0.2 2-theta degree.

13. The process according to claim 12, wherein the X-ray powder diffraction pattern further comprises peaks at about 65.5±0.2, 74.1±0.2, and 83.2±0.2 2-theta degree.

14. The process according to claim 1, being an electroless plating process.

15. A cobalt-iron alloy film, say cobalt-iron alloy film consisting of about 75-95wt. % of cobalt, 4.5-20 wt. % of iron and 0.5-5wt. % of phosphorus and being characterized with an X-ray powder diffraction pattern comprising peaks at about 43.2±0.2, 45.1±0.2, 50.4±0.2, 65.5±0.2, 74.1±0.2 and 83.2±0.22-theta degree.

16. The cobalt-iron alloy film of claim 15, wherein the X-ray powder diffraction pattern is shown in FIG. 2.

17. The cobalt-iron alloy film of claim 15, having a thickness between 200 nm and 2000 nm.

18. The cobalt-iron alloy film of claim 15, being part of a flip chip packaging, chip scale packaging or wafer level chip scale packaging.

19. The cobalt-iron alloy film of claim 15, being part of a printed circuit board or a light-emitting diode device.
